(19) United States
(12) Patent Application Publication
(10) Pub. No.: US 2011/0284820 A1
(43) Pub. Date: Nov. 24, 2011

(54) NANOWIRES ON SUBSTRATE SURFACES, METHOD FOR PRODUCING SAME AND USE THEREOF

(75) Inventors: Stefan Kudera, Stuttgart (DE); Eva Bock, Edenkoben (DE); Joachim P. Spatz, Stuttgart (DE); Liberato Manna, Lecce (IT)

(73) Assignees: ISTITUTO ITALIANO DI TECNOLOGIA, Genova (IT); MAX-PLANCK-GESELLSCHAFT ZUR FOERDERUNG DER WISSENSCHAFTEN E.V., Muenchen (DE)

(21) Appl. No.: 13/130,234

(22) PCT Filed: Nov. 20, 2009
(86) PCT No.: PCT/EP09/08277

§ 371 Date: Aug. 3, 2011

(30) Foreign Application Priority Data
Nov. 21, 2008 (DE) 10 2008 058 400.2

(51) Int. Cl. H01L 29/66; H01L 21/20; B82Y 40/00; B82Y 99/00

(52) U.S. Cl. 257/9; 438/478; 257/E21.09; 257/E29.168; 977/762

(57) ABSTRACT

The invention relates to a method for producing anchored nanowires on substrate surfaces. A method for producing anchored nanowires on a substrate which comprises no deposition steps from the gas phase with the steps:
a) providing a substrate surface having a predefined two-dimensional geometric arrangement of nanoparticles or nanoclusters;
b) contacting the substrate surface having the nanoparticles or nanoclusters with at least one solution of the material forming the nanowires, wherein the material forming the nanowires is deposited selectively on the nanoparticles or nanoclusters and grows further there. The method according to the invention preferably also comprises the steps of: a) applying a seed material to the nanoparticles or nanoclusters by contacting the substrate surface with a solution of the seed material such that the seed material is selectively deposited on the nanoparticles or nanoclusters; and step b) the material forming the nanowires is deposited selectively on the nanoclusters or nanoparticles provided with seed material and grows further there.

Nanowires and methods for producing the same are of great interest in many technical fields, for example in semiconductor technology, optics and photovoltaics, and a range of different approaches have been applied in order to produce such nanowires, that is to say fine wire- or filament-like structures with a diameter of typically 1-100 nm and lengths up to into the micrometer range, from various materials, generally from metals, semimetals and metal alloys, but also from organic compounds.

Methods for producing nanowires are for example described in Pearton et al., Journal of Nanoscience and Nanotechnology, Vol. 8, 99-110 (2008), Yu et al., J. Am. Chem. Soc. 2003, Vol. 125, 16168-16169, Fanfair and Korgel, Crystal Growth & Design 2005, Vol. 5, No. 5. 1971-1976, as well as in the patent applications US 2006/0057360 A1, US 2007/0194467 A1, US 2008/0047604 A1 and WO 2008/054378 A2.

Many methods of the prior art are however time- and cost-intensive, particularly methods which contain deposition steps from the gas phase, and/or do not enable sufficient control of the growth conditions or the achievement of a certain desired geometric arrangement of the nanowire structures on a substrate surface. Other production methods only deliver colloidal nanowires which are not anchored on a surface.

It was therefore an object of the present invention to provide anchored nanowires on a substrate surface in a certain geometric arrangement in the simplest, most material saving and most cost-effective manner possible.

This object is achieved according to the invention with the provision of the method according to Claim 1 and also of the nanowires according to Claim 10. Specific or preferred embodiments and aspects of the invention are the subject matter of the further claims.

### DESCRIPTION OF THE INVENTION

The method according to the invention for producing anchored nanowires on a substrate according to Claim 1 contains no deposition steps from the gas phase and comprises at least the following steps:
a) providing a substrate surface having a predefined two-dimensional geometric arrangement of nanoparticles or nanoclusters;
b) contacting the substrate surface having the nanoparticles or nanoclusters with at least one solution of the material forming the nanowires, the material forming the nanowires being deposited selectively on the nanoparticles or nanoclusters and grows further there.

The method according to the invention preferably further comprises that in step a) the application of a seed material onto the nanoparticles or nanoclusters by contacting the substrate surface with a solution of the seed material takes place such that the seed material is selectively deposited on the nanoparticles or nanoclusters; and in step b) the material forming the nanowires is deposited selectively on the nanoparticles or nanoclusters provided with seed material and grows further there.

The substrate surface is fundamentally not particularly limited and can comprise any material as long as it is durable under the conditions of the method according to the invention and does not impair or disturb the reactions taking place. The substrate can for example be selected from glass, silicon, metals, polymers, etc. For some applications, transparent substrates, such as glass or ITO on glass are preferred.

The predetermined two-dimensional geometric arrangement of the nanoparticles on the substrate surface has predetermined minimum or average particle spacings as a characteristic, wherein these predetermined particle spacings can be the same in all regions of the substrate surface or various regions can have different predetermined particle spacings. Such a geometric arrangement can fundamentally be realized with any suitable method of the prior art.

It is however preferred that the two-dimensional arrangement of nanoparticles or nanoclusters be generated using a micelle diblock copolymer nanolithography technology, as e.g. described in EP 1 027 157 B1 and DE 197 47 815 A1. In micellar nanolithography, a micellar solution of a block copolymer is deposited onto a substrate, e.g. by means of dip coating, and under suitable conditions forms an ordered film structure of chemically different polymer domains on the surface, which inter alia depends on the type, molecular weight and concentration of the block copolymer. The micelles in the solution can be loaded with inorganic salts which, following deposition with the polymer film, can be oxidized or reduced to inorganic nanoparticles. A development of this technology, described in the patent application DE 10 2007 017 032 A1, makes it possible to two-dimensionally set both the lateral separation length of the polymer domains mentioned and thus also of the resulting nanoparticles and the size of these nanoparticles by means of various measures so precisely that nanostructured surfaces with desired spacing and/or size gradients can be produced. Typically, nanoparticle arrangements produced with such a micellar nanolithography technology have a quasi-hexagonal pattern.

The providing of a substrate surface with a certain geometric arrangement of nanoparticles, including predetermined particles spacings and a predetermined particle size is an important general condition for the method according to the invention.

Fundamentally, the material of the nanoparticles or nanoclusters is not particularly limited and can comprise any material known in the prior art for such nanoparticles. Preferably, the material is selected from the group made up of Au, Pt, Pd, Ag, In, Fe, Zr, Al, Co, Ni, Ga, Sn, Zn, Ti, Si and Ge and particularly preferably is gold.

In a preferred embodiment of the method according to the invention, the nanoparticles are also coated with a seed material in step a), which mediates the adhesion and the growth of the actual nanowire material on these nanoparticles. This seed material is preferably selected from the group made up of Bi, In and alloys of these metals, whereby Bi is particularly preferred. In some cases, for example in the case of a combination of gold nanoparticles with ZnO or Si as nanowire material, the seed material may also be dispensable.

The coating typically takes place by means of dipping the substrate with the nanoparticles, preferably gold nanoparticles, into a hot solution of a salt of the seed material, e.g. Bi(III)2-ethylhexanoate for Bi, in a suitable solvent at a temperature in the range from 130° C. to 200° C., preferably from 160° C. to 170° C. In this case, the bismuth is selectively deposited on the nanoparticles. The dwell time determines the diameter of the bismuth layer on the nanoparticles. The growth process is stopped by taking the substrate out of the solution and washing the substrate, e.g. with isopropanol.

Typically, the material forming the nanowires is a semiconductor material. Preferably, the nanowire material is selected from the group made up of CdSe, CdTe, CdS, PbSe, PbTe, PbS, InP, InAs, GaP, GaAs, ZnO, (ZnMg)O, Si and doped Si.

For producing the nanowires according to the invention, the substrate is dipped with the optionally coated nanoparticles into at least one solution of the material provided for forming the nanowires. Conventionally, this material is a metal/semimetal or an alloy of metals/semimetals and the solution of this material used in step b) according to the invention comprises a solution of one or a plurality of salt(s) of this metal/semimetal or these metals/semimetals. In the case of nanowires made up of CdSe or CdTe, a solution used is for example a solution of cadmium stearate in tri-n-octylphosphine oxide (TOPO) or of cadmium oxide in TOPO and a phosphorus-containing acid with relatively long alkyl chain (e.g. “octadecylphosphonic acid”) or cadmium oxide in olive oil (according to Sapra et al., Journal of Materials Chemistry, 2006. 16(33) pp. 3391-3395), into which the substrate is dipped and suitable Se or Te compounds, e.g. n-R₃PSe or n-R₃PTe (with R=alkyl, e.g. butyl or octyl) are likewise added.

The temperature for the growth of the nanowires can be set in accordance with the requirement and as a function of the components used. In the case of the nanowires made from CdSe and CdTe, the temperature typically lies in a range from 150° C.-250° C. By varying the concentration of the components, e.g. Cd and Se/Te, the temperature and reaction time, the length of the nanowires can be varied. Typically, with the method according to the invention, nanowires with a length of approximately 10 nanometers to several micrometers are created.

In the exemplary embodiment, suitable conditions for producing nanowires according to the invention with CdSe are described in more detail. It will become clear for the person skilled in the art, however, that variations of these conditions as a function of the specific materials used may be required and can be determined without difficulty by means of routine experiments.

The production method according to the invention can be carried out in a very material saving manner by minimizing the quantity which flows over the substrates of the solutions used. A further advantage from the point of view of method technology with respect to known production methods for nanowires consists in the fact that the method according to the invention can be carried out in parallel with many samples/batches.

The method according to the invention delivers substrates with a defined arrangement of anchored nanowires in predetermined spacings, whereby the nanowires have a fixed epitaxial link with the nanoparticles of the substrate surface. It can be seen from FIGS. 1c and 1d that a nanoparticle can be the origin for more than one nanowire. The production of branched nanowires is also fundamentally possible.

The products of the method according to the invention offer a broad range of application options in the fields of electronics and piezoelectronics, particularly nanopiezoelectronics, semiconductor technology, optics, sensor technology, photovoltaics and generally chemical storage elements.

Some non-limiting examples for this are use in solar cells, transistors, diodes, chemical storage elements or sensors.

A particularly preferred application relates to the use in solar cells. Semiconductor nanowires and nanocrystals are, as is known, capable to absorb light in the visible spectrum efficiently. For most currently used nanocrystal-based solar cells, a mixture of colloidal nanocrystals with a conductive polymer (Kumar and Scholes, Microchimica Acta 2008, Vol. 160 (3), 315-325), or an electrolyte (Grätzel, Nature 2001, 414, 338) is used. An electron/hole pair which has been generated in a nanocrystal is separated on the crystal surface. One charge carrier type is transported by the polymer to an electrode, whilst the other is transported by the nanocrystals to the opposite electrode. This approach is generally limited by the lack of a percolating network of nanocrystals. The distance over which the charge carriers can be transported, is limited by the dimensions of the nanocrystals. The contact between the nanocrystals and the electrode is also often not optimal. As a consequence of the production process, the nanocrystals are generally coated with organic molecules which form an insulating layer between the nanocrystals and the electrode. By contrast, the use of nanowires which are fixedly anchored on a surface offers considerable advantages. If the surface is conductive, the charges generated in the absorption process can be stored directly. An arrangement of this type, with anchored nanowires based on ZnO which are dipped in a liquid electrolyte, has been suggested by Law et al, Nature Materials 2005, 4, 455-459. The synthesis method described there is not transferable to other nanowire materials such as CdSe and CdTe, however, and a substrate surface with a predetermined two-dimensional geometric arrangement for the growth of the nanowires is not used.

By using structured surfaces with a predetermined pattern according to the invention, it is possible to obtain a controlled and high density of nanowires, whereby the individual wires are present in a well separated manner in a desired spacing. In this manner the characteristics of the nanowire arrangement can be set particularly conveniently and finely. For example, the optimization of the density enables the use of a conductive polymer (see FIG. 2) instead of a fluid electrolyte, as described in Law et al. This is advantageous for applications in which there is a risk of an escape of fluid or evaporation of fluid, e.g. for thin film applications. By optimizing the density, a satisfactory penetration of the conductive polymer between the wires can be ensured, which is often problematic for conventional arrangements of nanowires.

### BRIEF DESCRIPTION OF THE FIGURES

FIG. 1 shows SEM images of samples in various stages of the production method according to the invention.
(a) initial substrate with a defined arrangement of gold nanoparticles; (b) following the deposition of bismuth on the gold nanoparticles; (c) short CdSe nanowires which grow on the Au/Bi nanoparticles; (d) long and dense arrangement of CdSe nanowires on the substrate.

FIG. 2 schematically shows the structure of an electrode arrangement using the nanowires produced according to the invention and anchored on a substrate as the element of a solar cell.

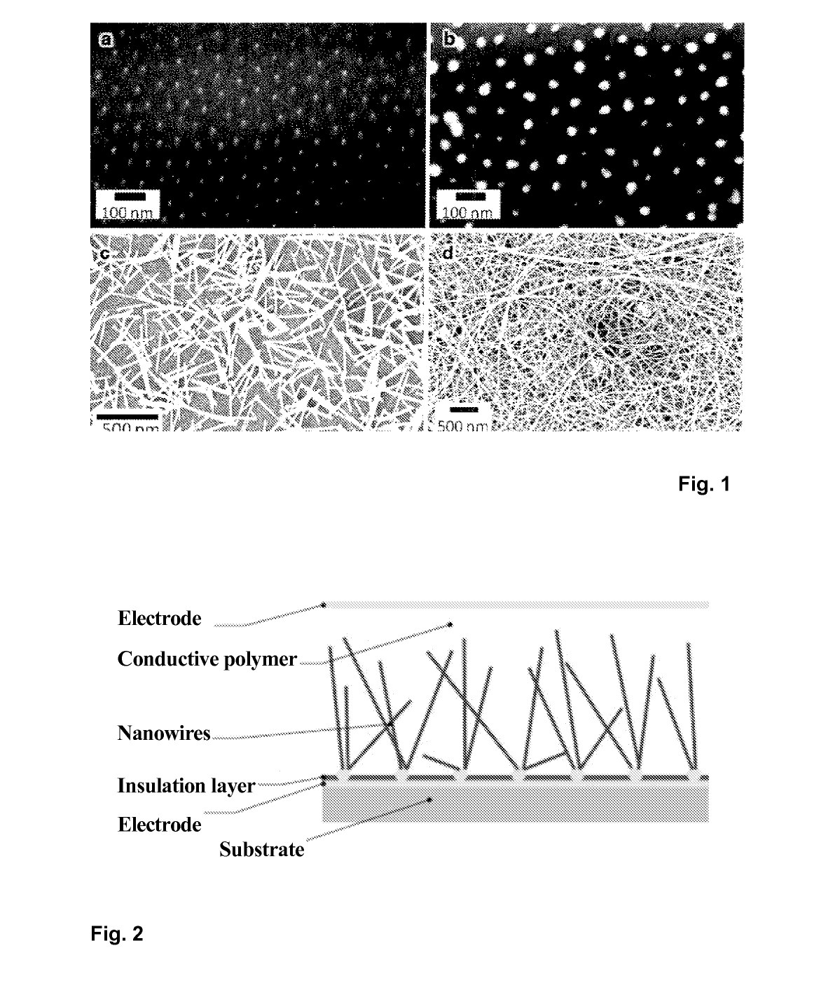

The following examples are used for more in depth explanation of the present invention, without limiting the same thereto, however.

### EXAMPLE

Production of CdSe Nanowires on a Substrate with an Arrangement of Gold Nanoparticles.

### 1. Providing the Substrate Surface

Initially, a substrate surface, e.g. glass or ITO on glass is coated with gold dots/gold nanoparticles in a defined arrangement by means of micellar nanolithography. In this step, one of the protocols described in EP 1 027 157 B1, DE 197 47 815 A1 or DE 10 2007 017 032 A1 can be followed. The method contains the deposition of a micellar solution of a block copolymer (e.g. polystyrene(n)-b-poly(2-vinylpyridine (m)) in toluene) onto the substrate, e.g. by means of dip coating, as a result of which an ordered film structure of polymer domains is formed on the surface. The micelles in the solution are loaded with a gold salt, preferably HAuCl₄ which, following deposition with the polymer film, is reduced to gold nanoparticles. The reduction can take place chemically, e.g. with hydrazine, or by means of energy-rich radiation, such as electron radiation or light. Preferably, after or at the same time as the reduction, the polymer film is removed (e.g. by means of plasma etching with Ar-, H- or O-ions).

Subsequently, the selective coating of the gold nanoparticles with bismuth takes place. To this end, initially 50 mg Bi[N(SiMe₃)₂]₃ (produced as described in Carmalt et al., Homoleptic Bismuth Amides. Inorg. Synth., 1996. 31: pp. 98-101), 0.1 ml Na[N(SiMe₃)₂] (from Sigma Aldrich, #36,805-9) and 20 ml of a polymer solution (42.6 g poly(l-vinylpyrrolidone)-graft-(1-hexadecene) from Sigma-Aldrich, #43,050-1 in 130 g 1,3-isopropylbenzene) is mixed in a flask and the following steps are carried out:
1.1 The substrates with the Au coating are hung in the solution.
1.2 The flask is briefly evacuated and filled with nitrogen a number of times.
1.3 Under nitrogen, the solution is heated to 150-170° C. and kept at this temperature for between 30 minutes and 5 hours.
1.4 The reaction on the substrates is stopped by taking the samples out of the solution.
1.5 The substrates are subsequently rinsed with isopropanol and stored for later experiments under a protective gas (nitrogen).

### 2. Production of the Semiconductor Nanowires

2.1 8 g of TOPO (tri-n-octylphosphine oxide from Strem Chemicals, #15-6661) and 30 mg Cd stearate (Strem Chemicals, #93-4820) are mixed in the flask.
2.2 The solution is heated to 100-150° C. and evacuated a number of times and then rinsed with nitrogen.
2.3 The solution is further heated to 210° C. under nitrogen and the samples are hung in the solution.
2.4 As soon as the temperature is stabilized, a selenium solution is injected: 400 mg TOP (tri-n-octylphosphine from Sigma-Aldrich #11,785-4) and 100 mg Se-TOP (200 mg selenium powder dissolved in 800 mg TOP).
2.5 The reaction is allowed to run for approx. 30 minutes and then the substrates are taken out of the solution.
2.6. The substrates are rinsed with isopropanol.

1. A method for producing anchored nanowires on a substrate, said method comprising the following steps:
a) providing a substrate surface having a predefined two-dimensional geometric arrangement of nanoparticles or nanoclusters;
b) contacting the substrate surface having the nanoparticles or nanoclusters with at least one solution of a material forming the nanowires, wherein the material forming the nanowires is deposited selectively on the nanoparticles or nanoclusters and grows further there,
wherein the method is free of gas phase deposition steps.

2. The method according to claim 1, wherein step a) further comprises an application of a seed material onto the nanoparticles or nanoclusters by contacting the substrate surface with a solution of the seed material such that the seed material is selectively deposited on the nanoparticles or nanoclusters and wherein the material forming the nanowires in step b) is deposited selectively on the nanoparticles or nanoclusters provided with the seed material.

3. The method according to claim 1, wherein the two-dimensional geometric arrangement of nanoparticles or nanoclusters on the substrate surface is produced using a micelle block copolymer nanolithography technology.

4. The method according to claim 1, wherein the material forming the nanowires is a metal/semimetal or an alloy of metals/semimetals and the at least one solution of the material used in step b) comprises a solution of one or a plurality of salt(s) of the metal/semimetal or the alloy of the metals/semimetals.

5. The method according to claim 1, wherein the material of the nanoparticles or nanoclusters is a member selected from the group consisting of Au, Pt, Pd, Ag, In, Fe, Zr, Al, Co, Ni, Ga, Sn, Zn, Ti, Si and Ge.

6. The method according to claim 5, wherein the nanoparticles or nanoclusters are gold nanoparticles or gold nanoclusters.

7. The method according to claim 2, wherein the seed material is a member selected from the group consisting of Bi, In and alloys of Bi and In.

8. The method according to claim 1, wherein the material of the nanowires is a semiconductor material.

9. The method according to claim 1, wherein the material of the nanowires is a member selected from the group consisting of CdSe, CdTe, CdS, PbSe, PbTe, PbS, InP, InAs, GaP, GaAs, ZnO, (ZnMg)O, Si and doped Si.

10. Nanowires which are anchored in a certain geometric arrangement on a substrate, obtainable with the method according to claim 1, wherein the two-dimensional geometric arrangement is predetermined by an arrangement of nanoparticles or nanoclusters on the substrate surface.

11. The nanowires according to claim 10, wherein the geometric arrangement comprises a hexagonal pattern.

12. The nanowires according to claim 10, wherein the material of the nanoparticles or nanoclusters is gold.

13. The nanowires according to claim 10, wherein the material of the nanowires is a member selected from the group consisting of CdSe, CdTe, CdS, PbSe, PbTe, PbS, InP, InAs, GaP, GaAs, ZnO, (ZnMg)O, Si and doped Si.

14. A method of using the nanowires according to claim 10 in electronics, piezoelectronics, semiconductor technology, sensor technology, optics or photovoltaics.

15. A solar cell, transistor, diode, sensor or chemical storage element, comprising nanowires according to claim 10.

16. A solar cell, transistor, diode, sensor or chemical storage element, comprising nanowires obtained using the method according to claim 1.
